(19) United States
(12) Patent Application Publication
(10) Pub. No.: US 2018/0294270 A1
(43) Pub. Date: Oct. 11, 2018

(54) VERTICAL STACK MEMORY DEVICE

(71) Applicant: SAMSUNG ELECTRONICS CO., LTD., SUWON-SI (KR)

(72) Inventors: KYUNG-HWAN LEE, HWASEONG-SI (KR); MIN-KYUNG BAE, SEOUL (KR); BYOUNG-TAEK KIM, HWASEONG-SI (KR); HYE-JIN CHO, SEOUL (KR); YONG-SEOK KIM, SUWON-SI (KR); TAE-HUN KIM, GWACHEON-SI (KR); JUN-HEE LIM, SEOUL (KR)

(21) Appl. No.: 15/815,164

(22) Filed: Nov. 16, 2017

(30) Foreign Application Priority Data
Apr. 5, 2017 (KR) 10-2017-0044279

(51) Int. Cl. H01L 27/1157; H01L 27/11582

(52) U.S. Cl. CPC H01L 27/1157; H01L 27/11582

(57) ABSTRACT

A vertical stack memory device includes a doped semiconductor substrate having a common source to which a source power is applied and a low band gap layer that is spaced apart from the common source, and the low band gap comprising low band gap materials. A stack gate structure has gate electrodes and insulation interlayer patterns that are alternately and vertically stacked on the substrate in a first direction. A channel structure penetrates through the stack gate structure in the first direction. The channel structure makes contact with the low hand gap layer. A charge storage structure is interposed between the stack gate structure and the channel structure. The charge storage structure is configured to selectively store charge and to provide the stored charge to a memory cell, the stack gate structure, and the channel structure.

### CROSS-REFERENCE TO RELATED APPLICATIONS

This application claims priority under 35 U.S.C. § 119 to Korean Patent Application No. 10-2017-0044279 filed on Apr. 5, 2017 in the Korean intellectual Property Office, the contents of which are incorporated by reference herein in its entirety.

### TECHNICAL FIELD

The present disclosure relates to a memory device, and more particularly, to a vertical stack memory device.

### DISCUSSION OF THE RELATED ART

NAND flash memory devices generally store data therein through a programming operation. Stored data may be removed from the flash memory device through an erasing operation. In a flat type NAND flash memory device, the data erase operation is generally performed by a hulk erase operation in which a negative bias is applied to the control gate of the flash memory cell and a positive bias is applied to the channel of the flash memory cell.

However, in a vertical NAND flash memory device, in which the memory cells of the flat type NAND memory device are vertically stacked, the data erase is performed by either the bulk erase operation or a GIDL erase operation, depending on the stack structure of the memory cells in the vertical NAND memory device. According to the GIDL erase operation, a plurality of electron holes may be generated by gate-induced drain leakage (GIDL) current and the electron holes may be replaced with charge in the charge trap layer of the NAND memory device.

The bulk erase operation is not performed in a BiCS (bit cost scaling) type vertical NAND memory device because a U-shaped cell string is provided into a single string by a back gate, so the cell data in the BiCS type vertical NAND memory device is erased by the GIDL erase operation. In contrast, the cell data in a TCAT (terabit cell array transistor) type vertical NAND memory device is erased by either the GIDL erase operation or the bulk erase operation, because the TCAT type vertical NAND memory device has a pair of separated channel columns that may be connected to the same channel layer and a pair of cell strings that are connected to the respective channel column.

Recently, the GIDL erase operation, rather than the bulk erase operation, has been more widely used for erasing data in the NAND memory device as modern NAND memory devices tend to be vertical NAND memory.

### SUMMARY

A vertical stack memory device includes a doped semiconductor substrate having a common source to which a source power is applied and a low band gap layer that is spaced apart from the common source, and the low band gap comprising low band gap materials. A stack gate structure has gate electrodes and insulation interlayer patterns that are alternately and vertically stacked on the substrate in a first direction. A channel structure penetrates through the stack gate structure in the first direction. The channel structure makes contact with the low band gap layer. A charge storage structure is interposed between the stack gate structure and the channel structure and selectively store charges. The gate electrode and the charge storage structure and the channel structure corresponding to the gate electrode is configured into a memory cell of the vertical stack memory device.

A vertical stack memory device includes a doped semiconductor substrate having a common source configured to receive a source power. A stack gate structure has gate electrodes and insulation interlayer patterns that are alternately and vertically stacked on the substrate in a first direction. A channel structure penetrates through the stack gate structure in the first direction and is connected to the substrate through a low band gap via-pattern comprising low band gap materials. A charge storage structure is interposed between the stack gate structure and the channel structure and selectively store charges. The gate electrode and the charge storage structure and the channel structure corresponding to the gate electrode is configured into a memory cell of the vertical stack memory device.

A stacked memory device includes a semiconductor substrate. A plurality of memory cells is stacked vertically on the semiconductor substrate. The semiconductor substrate includes a common source for the plurality of memory cells. The semiconductor substrate includes a low band gap layer comprising one or more low band gap materials. A stack gate structure is provided for the plurality of memory cells. A channel structure is provided for the plurality of memory cells. A charge storage structure is configured to store charge and to provide the stored charge to the plurality of memory cells.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a perspective view illustrating a vertical stack memory device in accordance with an exemplary embodiment of the present invention;

FIG. 2 is a plan view illustrating the vertical stack memory device shown in FIG. 1;

FIG. 3 is a cross sectional view taken along a line I-I′ of FIG. 2;

FIG. 4 is a view illustrating lattice structures of the substrate and the low band gap layer at a boundary area thereof;

FIG. 5 is an enlarged view illustrating the charge storage structure of the vertical stack memory device shown in FIG. 1;

FIG. 6 is a perspective view illustrating a first modification of the vertical stack memory device shown in FIG. 1 in accordance with exemplary embodiments of the present invention;

FIG. 7 is a cross sectional view taken along a bit line of the vertical stack memory device shown in FIG. 6;

FIG. 8 is a perspective view illustrating a second modification of the vertical stack memory device shown in FIG. 1 in accordance with exemplary embodiments of the present invention;

FIG. 9 is a cross sectional view taken along a bit line of the vertical stack memory device shown in FIG. 8;

FIG. 10 is an enlarged view illustrating the charge storage structure of the second modified memory device shown in FIG. 8;

FIG. 11 is a perspective view illustrating a third modification of the vertical stack memory device shown in FIG. 1 in accordance with exemplary embodiments of the present invention; and

FIG. 12 is a cross sectional view taken along a bit line of the vertical stack memory device shown in FIG. 11.

### DETAILED DESCRIPTION OF THE EMBODIMENTS

In describing exemplary embodiments of the present disclosure illustrated in the drawings, specific terminology is employed for sake of clarity. However, the present disclosure is not intended to be limited to the specific terminology so selected, and it is to be understood that each specific element includes all technical equivalents which operate in a similar manner. Like reference numerals may refer to like components throughout the specification and the drawings.

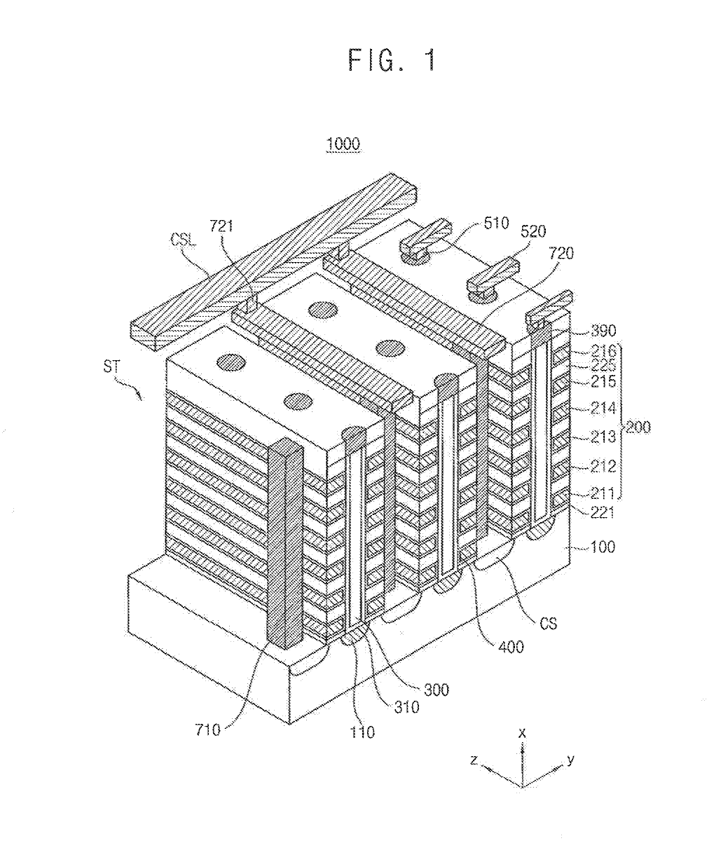

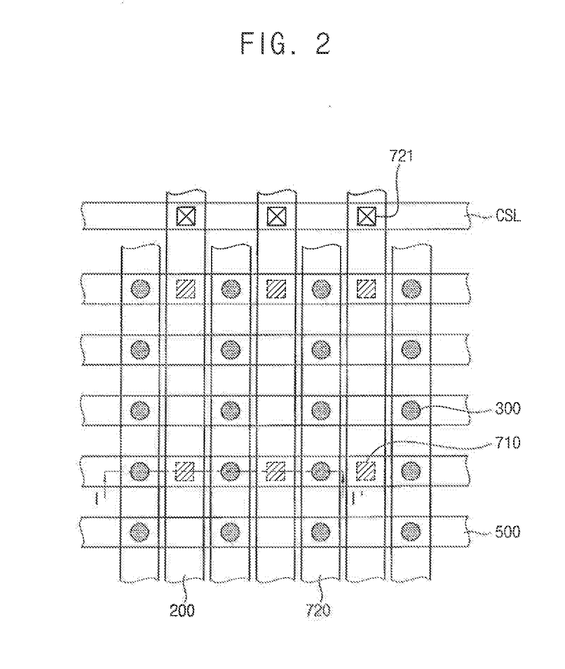

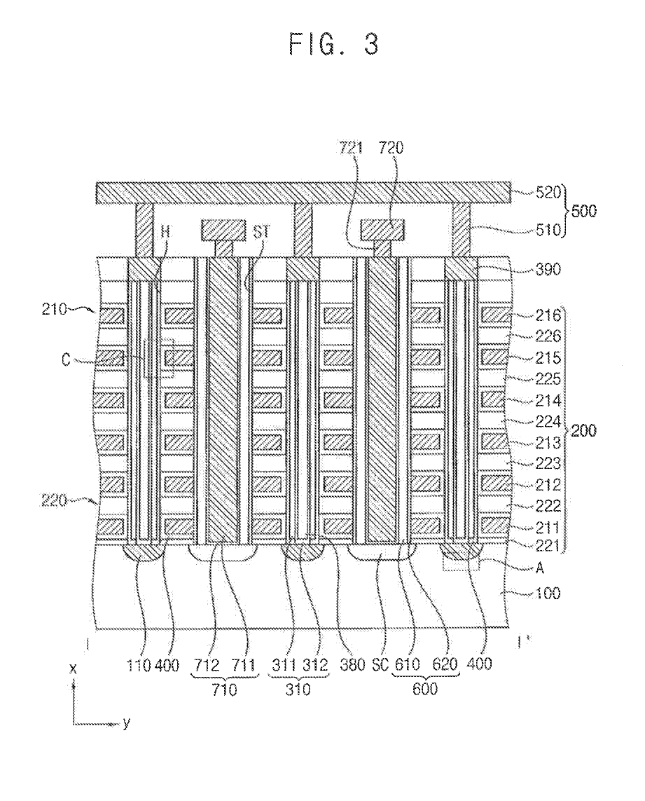

FIG. 1 is a perspective view illustrating a vertical stack memory device in accordance with an exemplary embodiment of the present invention. FIG. 2 is a plan view illustrating the vertical stack memory device shown in FIG. 1. FIG. 3 is a cross sectional view taken along a line I-I′ of FIG. 2.

Hereinafter, a vertical direction substantially perpendicular to a substrate is defined as a first direction x and a pair of crossing horizontal directions substantially parallel with the substrate are defined as second and third directions y and z. The second and third directions may be substantially perpendicular to each other. In addition, the present inventive concept is described herein with reference to vertical NAND flash memory devices. However, the present inventive concept may also be applied to any other memory devices as well as vertical NAND flash memory devices as long as a GIDL erase operation may be used to erase cell data.

Referring to FIGS. 1 to 3, a vertical stack memory device 1000, in accordance with exemplary embodiments of the present invention, may include a semiconductor substrate 100 doped with dopants and having a common source CS and a low band gap layer 110 that is spaced apart from the common source CS. The low hand gap layer 110 comprises low band gap materials. The vertical stack memory device 1000 further includes a stack gate structure 200 having gate electrodes and insulation interlayer patterns that are alternately and vertically stacked on the substrate in a first direction x, a channel structure 300 penetrating through the stack gate structure 200 in the first direction x and making contact with the low band gap layer 110, and a charge storage structure 400 interposed between the stack gate structure 200 and the channel structure 300. The charge storage structure 400 selectively stores charge to provide a memory cell C for storing data together with the stack gate structure 200 and the channel structure 300. A separation trench ST may extend in a third direction z on the substrate 100 and a plurality of the stack gate structures 200 may be separated by the separation trench ST along the second direction y. A source power may be applied to the common source CS and a drain. power may he applied to the channel structure 300. A bit line structure 500 is connected to the channel structure 300. A source line structure may be connected to the substrate 100 through the separation trench ST.

The substrate 100 may include a semiconductor substrate having a preset polarity type. For example, the substrate 100 may include a silicon substrate having single crystalline or polycrystalline silicon (Si), a silicon germanium (SiGe) substrate and a silicon-on-insulator (SOT) substrate in which a semiconductor base board such as silicon germanium (SiGe) substrate, an insulation layer on the base board and a semiconductor layer such as a single crystalline silicon layer or a polycrystalline silicon layer on the insulation layer. As described in detail hereinafter, the substrate 100 may have various compositions and structures according to the composition of the low band gap layer 110.

The common source CS and the low band gap layer 110 may be provided along with the substrate 100. Dopants having a preset polarity type for the common source CS may be doped at a surface portion of the substrate 100 and the common source CS may be disposed on the substrate 100. The source power may be applied to the common source CS. The low band gap layer 110 may also be disposed on the substrate 100 in such a configuration that the low band gap layer 110 may be spaced apart front the common source CS in the second direction y.

In an exemplary embodiment of the present invention, impurities or dopants having the polarity type may be implanted onto the surface portion of the substrate 100 that may be exposed through the separation trench ST, thereby forming the common source CS on the bottom of the separation trench ST. Thereafter, the separation trench ST may be filled with insulation materials and thus an insulative line pattern 600 may be arranged in the third direction z and the neighboring stack gate structures 200 may be electrically insulated from each other by the insulative line pattern 600 in the separation trench ST.

The common source CS may be shaped as a line extending in the third direction z. A pair of the adjacent common sources CS may be spaced apart from each other in the second direction by the combination of the stack gate structure 200 and the channel structure 300. For example, the dopants may include p-type impurities such as boron (B) and indium (In) and a-type impurities such as phosphorus (P) and arsenic (As).

The stack gate structures 200 may be separated by the insulative line pattern 600 in the separation trench ST and each of the stack gate structures 200 may function as a vertical single cell string of the vertical stack memory device 1000, such as a vertical NAND flash memory device.

The low band gap layer 110 may be disposed on the substrate 100 and may be shaped as a line extending in the third direction z. The low band gap layer 110 may be spaced apart from the common source CS in the second direction y. Low band gap materials may be implanted at the surface portions of the substrate 100 under the channel structure 300, so the low hand gap layer 110 may make contact with the channel structure 300. Accordingly, the drain power may be applied to the low band gap layer 110 through the bit line structure 500.

For example, a channel hole (H) may be arranged through the stack gate structure 200 and the low band gap layer may be formed on a portion of the substrate 100 that may be exposed through the channel hole H before the channel hole H may be filled up with the channel structure 300. The low band gap layer 110 may be formed by an implantation process or a deposition process using the low band gap materials. The low band gap layer 110 may also be formed by an expitaxial growth process using the low band gap materials. A seed layer comprising the low band gap materials may be first formed on a bottom of the channel hole H (e.g., on the portion of the substrate 100 exposed through the channel hole H) and the low band gap layer 110 may be grown to a desired height along the channel hole H by a selective expitaxial growth (SEG) process.

A band gap is an energy gap of a crystalline material having a lattice structure between a valence band and a conduction band. Thus, the band gap of the crystalline material acts as an energy barrier for transferring electrons from the valence band, which determines insulation characteristics of the crystalline material, to the conduction band, which determines conduction characteristics of the crystalline materials. When the band gap of the crystalline material is sufficiently small, the electrons in the valence band are likely to move to the conduction band with ease in the crystalline material and thus the crystalline material has conduction characteristics rather than insulation characteristics. In contrast, when the hand gap of the crystalline material is sufficiently large, the electrons in the valence band are hard to move to the conduction band in the crystalline material and thus the crystalline material has insulation characteristics rather than conduction characteristics. As the electrons move to the conduction band from the valence band in the crystalline material, the number of free electrons increases in the conduction band and the number of electron holes increases in the valence band, which changes the conduction characteristics of the crystalline material. Accordingly, when the band gap of the crystalline material is sufficiently small, a relatively large number of electrons and holes may be generated under the same external power to the crystalline material, and the electrons and holes may be generated, in sufficient numbers, using a relatively small amount of external power provided to the crystalline material.

The low band gap layer 110 may include low band gap materials in which the electrons may tend to move from the valence band to the conduction band using a relatively small amount of power such as a gate-induced drain leakage (GIDL) current. For example, the low band gap material of the low band gap layer 110 may be activated by the GIDL currents and may generate the electron holes therein. A sufficient number of electron holes may be generated from the low band gap layer 110 just by the relatively small amount of power of the GIDL current of the vertical stack memory device 1000. The electron holes may be transferred to the charge storage structure 400 of a selected memory cell and the charge may be eliminated from the selected memory cell. For example, the digital data of the selected memory cell C may be erased by the electron holes generated from the low band gap layer 110 by the GIDL currents.

Particularly, since the band gap of the low band gap layer 110 may be sufficiently small, there may be a sufficient number of the electron holes even though the drain power to the channel structure 300 and the intensity of the GIDL currents may be unchanged or the same in the vertical stack memory device 1000. As a result, a larger number of electron holes may be transferred to the selected cell and a larger number of the charges may be combined with the electron holes in the charge storage structure 400 of the selected cell at the same time, thereby increasing the efficiency of the GIDL erase operation in the selected cell of the vertical stack memory device 1000.

Therefore, the generation rate of the electron holes and the efficiency of the GIDL erase operation may increase under the same or unchanged drain power of the vertical stack memory device 1000. For example, the erase efficiency of the vertical stack memory device 1000 may increase without any power increase to the channel structure of the vertical stack memory device 1000.

For example, examples of the low band gap material for the low band gap layer 110 may include silicon germanium (SiGe), germanium (Ge), indium arsenide (InAs), gallium antimonide (GaSb), etc. These may be used alone or in combinations thereof.

For example, the low band gap layer 110 may have a lattice structure of which the inter-atomic distance may be greater than that of the substrate 100. Thus, a compressive stress may be applied to the low band gap layer 110 at the boundary area between the substrate 100 and the low band gap layer 110, so the effective mass of each electron hole may be reduced by the compressive stress. Therefore, a larger amount of electron holes may be transferred to the selected cell by the same control gate bias of the vertical stack memory device 1000, thereby increasing the transfer efficiency of the electron holes in the GIDL erase operation.

The electrons and holes may be generated by the GIDL currents that may be leaked from the drain electrode of a ground selection transistor which may be closest to the substrate 100 among the transistors of the cell string in the vertical stack memory device 1000.

Thus, the low band gap layer 110 may be under compressive stress at the surface portion of the substrate 100.

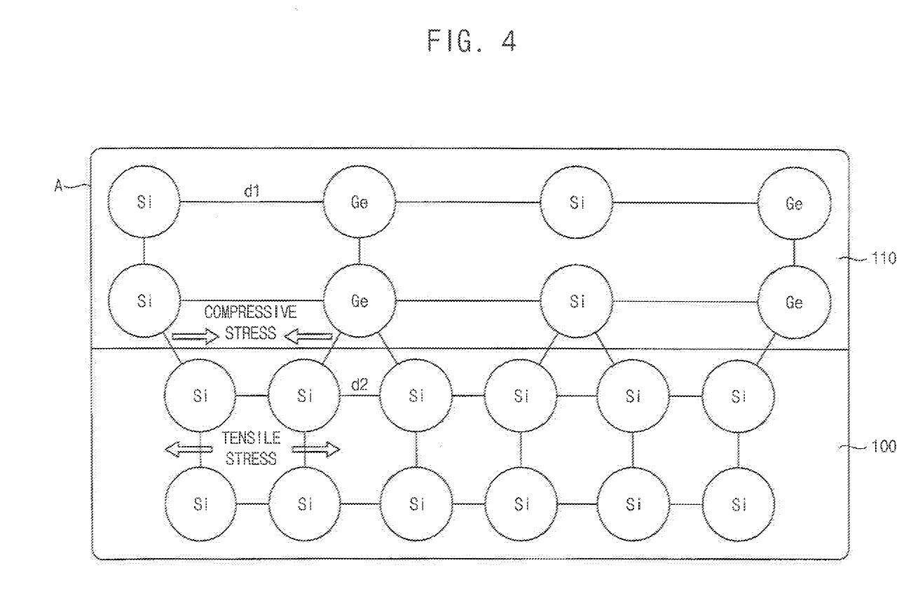

FIG. 4 is a view illustrating lattice structures of the substrate and the low band gap layer at a boundary area thereof. In FIG. 4, a silicon (Si) substrate may be used as the substrate 100 and a silicon germanium (SiGe) layer may be used as the low band gap layer 110. However, the present invention is not limited to this particular arrangement and other materials may be used in the substrate 100 and the low band gap layer 110.

Referring to FIG. 4, since the inter-atomic distance d1 of the lattice structure of silicon germanium (SiGe) may be much larger than the inter-atomic distance d2 of the lattice structure of silicon (Si), compressive stress may be applied between adjacent silicon (Si) and germanium (Ge) atoms of the low band gap layer 110 and tensile stress may be applied between adjacent silicon (Si) atoms of the substrate 100 at the boundary area of the substrate 100 and the low band gap layer 110.

The compressive stress between the adjacent silicon (Si) and germanium (Ge) atoms of the low band gap layer 110 may distort the shape of an energy-kinetics diagram (E-K diagram) which may reduce the effective mass and the band gap of the F-N tunneling charges. Therefore, the effective mass of the electron holes, which may be generated from the low band gap layer 110 by the GIDL currents, may also be reduced by the compressive stress, and thus the electron holes may be transferred to the charge storage structure 400 of the selected cell for a shorter time. For example, the transfer efficiency of the electron holes may increase due to the compressive stress of the low band gap layer 110.

Accordingly, a larger amount of the electron holes may be generated from the low band gap layer 110 due to the low band gap and the transfer efficiency of the electron holes may increase by controlling the inter-atomic distance of the low band gap layer 110, thereby increasing the efficiency of the GIDL erase operation in the vertical stack memory device 1000.

A plurality of the stack gate structures 200 may be arranged on the substrate 100 in such a configuration that the neighboring stack gate structures 200 may be separated from the insulative line pattern 600 in the separation trench ST along the second direction y and each of the stack gate structures 200 may extend in the third direction z. The stack gate structure 200 may include a gate structure 210 and an insulation pattern 220 enclosing the gate structure 210 that may be alternately stacked on the substrate 100 along the first direction x.

Referring again to FIGS. 1 to 3, the gate structure 210 may include a plurality of gate electrodes 211 to 216 that may be vertically stacked on the substrate 100 and the insulation pattern 220 may include a plurality of insulation interlayer patterns 221 to 226 for electrically insulating the gate electrodes 211 to 216 from one another. For example, a first insulation interlayer pattern 221 may be arranged on the substrate 100 and first to sixth gate electrodes 211 to 216 may be vertically arranged on the first insulation interlayer pattern 221 alternating with the second to sixth insulation interlayer patterns 222 to 226.

For example, the gate structure 210 may include doped silicon, a low resistive metal such as tungsten (W), titanium (Ti), tantalum (Ta) and platinum (Pt), a metal nitride, a metal silicide and compositions thereof. A barrier layer (not shown) may be further provided between the gate structure 210 and the insulation pattern 220 for preventing metal diffusion of the gate structure 210.

While first to sixth gate electrodes 211 to 216 may be stacked on the substrate 100, there may be more or less than six gate electrodes used as the gate structure 210. The number of gate electrodes used may depend on the performance and device characteristics of the vertical stack memory device 1000.

The first gate electrode 211 may be provided as a gate electrode for a ground selection transistor (GST) and the sixth gate electrode 216 may be provided as a gate electrode for a string selection transistor (SST). The second to fifth gate electrodes 212 to 215 may be provided as gate electrodes of cell transistors (CT). The GST, CT and the SST may be vertically arranged in series along the first direction x and may be disposed in a vertical cell string of the vertical stacked NAND flash memory device. A pair of vertical cell strings may be combined with the channel structure 300.

The vertically stacked gate electrodes 211 to 216 may be electrically insulated by the insulation pattern 220. The first insulation interlayer pattern 221 may be interposed between the substrate 100 and the first gate electrode 211. The second to sixth insulation interlayer patterns 222 to 226 may be interposed between the vertically stacked gate electrodes. The number of the insulation interlayer patterns may be selected according to the number of the stacked gate electrodes used. The insulation pattern 220 may include silicon oxide.

A thickness of each insulation interlayer pattern may be varied according to the device characteristics and manufacturing conditions of the vertical stack memory device 1000. Particularly, the first insulation interlayer pattern 221 may have a smaller thickness than the second to sixth insulation interlayer patterns 222 to 226.

The channel structure 300 may extend through the stack gate structure 200 in the first direction x and a plurality of the channel structures 300 may be arranged in the third direction z by the same gap distance. Thus, the channel structures 300 may be provided as a channel series along the third direction z and the adjacent channel series may be spaced apart by the insulative line pattern 600 in the separation trench ST.

A plurality of the channel series extending in the third direction z may be spaced apart from each other in the second direction y. A plurality of the channel structures 300 may be arranged in a matrix on a surface defined by the second and third directions y and z, thereby providing a channel array on a y-z surface of the vertical stack memory device 1000.

For example, the channel structure 300 may fill the channel hole H through the gate structure 210 and the insulation pattern 220 and reach the low band gap layer 110. Thus, a lower portion of the channel structure 300 may make contact with the low band gap layer 110 and an upper portion of the channel structure 300 may make contact with the bit line structure 500. A contact pad 390 may be further provided with the upper portion of the channel structure 300, to thereby reduce the contact resistance between the channel structure 300 and the bit line structure 500.

The channel structure 300 may include a semiconductor layer 310 that may comprise a semiconductor material and may be arranged on a sidewall of the channel hole H. The semiconductor layer 310 may include a first layer 311 and a second layer 312 that is disposed on the first layer 311. The first layer 311 may make contact with the charge storage structure 400 and the second layer 312 may be disposed on the first layer 311. The first layer 311 may function as a spacer for covering the charge storage structure 400 and the second layer 312 may cover the first layer 311 and the low band gap layer 110. The semiconductor layer 310 may include a silicon layer doped with dopants and may function as channel layer of the vertical stack memory device 1000.

The channel structure 300 may be shaped as a cylindrical layer having a central space therein. In such a case, the central space of the cylindrical layer may be filled with an insulative filler 380 such as a silicon oxide filler. Alternatively, the channel structure 300 may be shaped as a column having no central space therein. In such a case, the channel hole H may be filled only with the semiconductor layer 310.

An upper portion of the channel hole H may be filled with the contact pad 390 that may be in contact with the bit line structure 500. Thus, a contact area of the semiconductor layer 310 that makes contact with the contact pad 390 may function as a drain junction area of the vertical stack memory device 1000. Channel areas of the semiconductor layer 310 adjacent to each of the gate electrodes 211 to 216 may function as a channel layer of the memory cell C in which the respective gate electrode may function as a control gate.

Thus, the channel structure 300 may be in contact with the bit line structure 500 at the upper portion and may be in contact with the low band gap layer 110 at the lower portion. The low band gap layer 110 may be arranged around the common source CS in the substrate 100. Therefore, when the drain power may be applied to the channel structure 300, the GIDL currents generated from a drain junction of the GST, which may be closest to the substrate 100, may be applied to the low band gap layer 110 and a sufficient amount of electron holes may be generated from the low band gap layer 110.

A reverse bias may be applied to at least one of the second to fifth gate electrodes 212 to 215 and at least one of the memory cells may be selected as a selection cell from which the data may be erased. The electron holes of the low band gap layer 110 may be transferred to the charge storage structure 400 of the selection cell and may be combined with the charges in the charge storage structure 400. For example, the digital data of the selection cell may be erased by the GIDL erase operation using the electron holes that may be transferred from the low band gap layer 110.

Particularly, a larger amount of the electron holes may be generated from the low band gap layer 110 due to the low band gap material and the transfer efficiency of the electron holes to the selection cell may increase due to the lattice structure of the low band gap layer 110, which may sufficiently increase the GIDL erase efficiency of the vertical stack memory device 1000.

The charge storage structure 400 may be interposed between the stack gate structure 200 and the channel structure 300 and the charges may be selectively trapped by the charge storage structure 400.

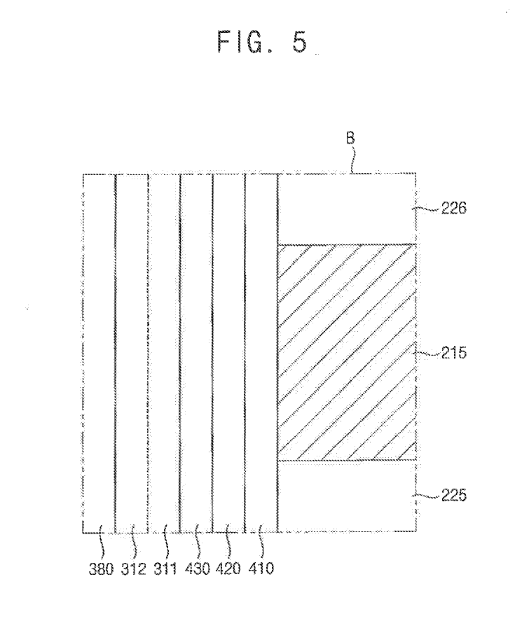

FIG. 5 is an enlarged view illustrating the charge storage structure of the vertical stack memory device shown in FIG. 1. Particularly, the memory cell C of the vertical stack memory device 1000 is illustrated in detail in FIG. 5.

Referring to FIG. 5, the charge storage structure 400 may include a blocking pattern 410 extending in the first direction x and covering the stack gate structure 200, a tunnel insulation pattern 430 extending in the first direction and enclosing the channel structure 300 and a charge trap pattern 420 interposed between the blocking pattern 410 and the tunnel insulation pattern 430 and selectively trapping charges.

The blocking pattern 410 may include a high dielectric layer having a relatively high dielectric constant. For example, the blocking pattern 410 may include a single layer comprising silicon oxide, aluminum oxide, hafnium oxide or a high-k material or a multilayer in which a silicon oxide layer and a high-k layer may be stacked.

The charge trap pattern 420 may make contact with the blocking pattern 410 and may extend in the first direction x continuously or discontinuously (intermittently). The charge may be selectively trapped in the charge trap pattern 420 to thereby program data into the memory cell C. The charge may be selectively eliminated from the charge trap pattern to thereby erase data from the memory cell C. For example, the charge trap pattern 420 may comprise a nitride such as silicon nitride and/or silicon oxynitride.

The tunnel insulation pattern 430 may make contact with an outer surface of the channel structure 300 and may extend in the first direction x. Thus, the tunnel insulation pattern 430 may be shaped into a cylinder of which the bottom may be open. The tunnel insulation pattern 430 may comprise an oxide such as silicon oxide.

The gate electrodes 211 to 216 may be electrically connected to each other in series between the bit line structure 500 and the source line structure, so the vertical series of the gate electrodes 211 to 216 may function as a single cell string of the vertical stack memory device 1000 of which both ends may be connected to the bit line structure 500 and the source line structure. A single cell string may include one SST, one GST and a plurality of the CTs that may make a simultaneous contact with the channel structure 300.

GST may include the first gate electrode 211 that may be connected to a ground selection line (GSL) and SST may include the sixth gate electrode 216 that may be connected to a string selection line (SSL). CTs may include second to fifth gate electrodes 212 to 215 that may be connected to word lines (WL).

The bit line structure 500 may include a bit line plug 510 making contact with the contact pad 390 and a bit line 520 making contact with the bit line plug 510 and extending in the second direction y.

The common source CS may be disposed at a bottom of the separation trench ST. The separation trench ST may be filled up with the insulative line pattern 600 having a vertical spacer 610 and a device isolation pattern 620. The vertical spacer 610 may extend in the first direction x and may cover the stack gate structure 200. The vertical spacer 610 may include insulation materials such as silicon oxide, silicon nitride silicon oxynitride and aluminum oxide. These may be used alone or in combinations thereof. The inner space of the separation trench ST defined by the vertical spacer 610 may be filled up with the device isolation pattern 620.

The source line structure may include a source interconnector 710 and a source line 720 connected to the source interconnector 710. The source interconnector 710 may extend through the device isolation pattern 620 in the first direction x and may make contact with the common source CS. The source line 720 may extend in the third direction z on the device isolation pattern 620 and may be connected to the source interconnector 710. A plurality of the source lines 720 may be connected to a single common source line CSL through a source contact 721. The common source line CSL may extend in the second direction y.

A plurality of the source interconnectors 710 may be arranged in series along the third direction z and may be spaced apart from each other by the same gap distance. For example, the source interconnector 710 may include a source plug 711 and a source barrier layer 712 enclosing the source plug 711.

The bit line 520 may be arranged over the source line 720 and may extend in the second direction y in parallel with the common source line CSL.

According to exemplary embodiments of the present invention, the low band gap layer 110 may be disposed at the surface portions of the substrate 100 close to the drain region of the GST, so a sufficient amount of the electron holes may be generated from the low band gap layer 110 by minute GIDL currents. Therefore, the electron holes may be generated without an increase of the drain power and a larger amount of the electron holes may be transferred to the selection cell, which may increase the GIDL erase efficiency.

In addition, the low band gap layer 110 may include such a lattice structure that the inter-atomic distance may be greater than surrounds (e.g., the substrate 100), so the compressive stress may be applied to the atoms of the low hand gap layer 110 at the boundary area. Accordingly, the effective mass of the electron holes may be reduced due to the compressive stress and a larger amount of the electron holes may be transferred to the selection cell under the same control gate bias, thereby increasing the GIDL erase efficiency.

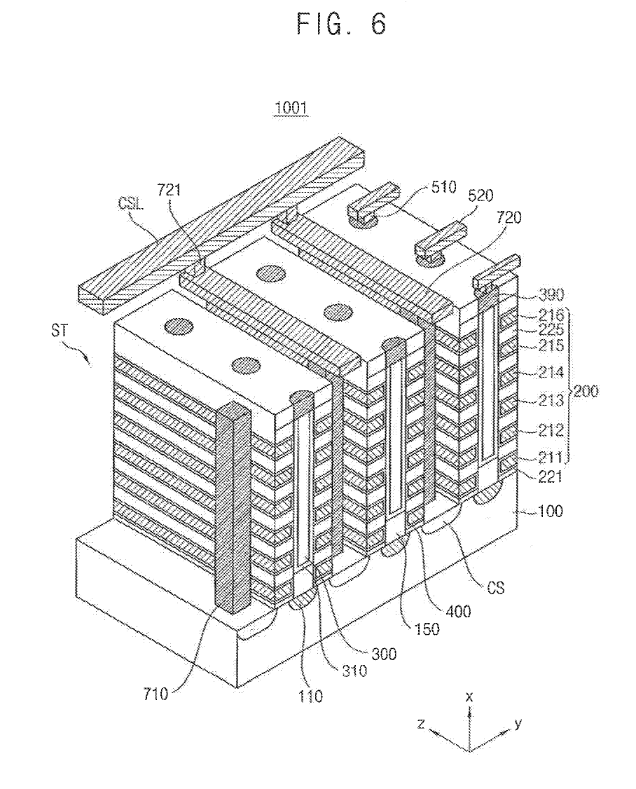

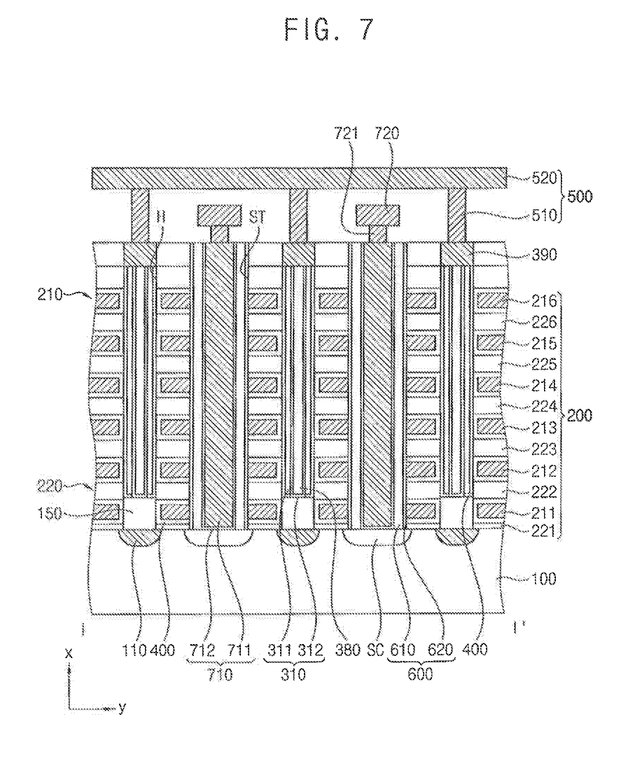

FIG. 6 is a perspective view illustrating a first modification of the vertical stack memory device shown in FIG. 1. FIG. 7 is a cross sectional view taken along a bit line of the vertical stack memory device shown in FIG. 6.

in FIGS. 6 and 7, the first modified memory device 1001 may have substantially the same structures as the vertical stack memory device 1000 except for the low resistive pattern interposed between the low band gap layer 110 and the channel structure 300. Thus, in FIGS. 6 and 7, the same reference numerals denote the same element in FIG. 1 and any further detailed descriptions on the same element will be omitted.

Referring to FIGS. 6 and 7, the first modified memory device 1001 may further include a low resistive pattern 150 that may be interposed between the low band gap layer 110 and the channel structure 300. Thus, the contact resistance between the low band gap layer 110 and the channel structure 300 may be sufficiently reduced by the low resistive pattern 150.

For example, the low resistive pattern 150 may include an epitaxial pattern on the low band gap layer 110. A seed layer may be firstly formed on the low band gap layer 110 and then the low resistive pattern 150 may be grown to a desired height along the first direction x by a selective epitaxial growth (SEG) process. The compositions and structures of the low resistive pattern 150 may be varied according to the compositions of the low band gap layer 110 and the channel structure 300 and the structural features of the channel structure 300.

Here, the low resistive pattern 150 may comprise single crystalline silicon (Si) or single crystalline silicon germanium (SiGe). Some dopants may be selectively doped into the low resistive pattern 150, where desired. The low resistive pattern 150 may be shaped into a column such as a circular column, an elliptical column, or a rectangular column and a pillar.

The height of the low resistive pattern 150 may be controlled by the growth rate of the SEG process. For example, the low resistive pattern 150 may be grown to such a height such that an upper surface of the low resistive pattern 150 may be lower than a bottom surface of the second gate electrode 212 or an upper surface of the second insulation interlayer pattern 222.

For example, when the low band gap layer 110 may be used as the seed layer for the low resistive pattern 150, the low resistive pattern 150 may also comprise the low band gap materials. In such a case, the low band gap layer 110 may extend substantially over the first gate electrode 211, functioning as the gate electrode of the GST.

Accordingly, more plentiful low band gap materials may be provided with the first modified memory device 1001, thereby increasing the generation efficiency of the electron holes. For example, the gate electrode of the GST may be sufficiently covered by the extended low band gap layer and thus the operation sensitivity of the GILL erase may be increased in the first modified memory device 1001.

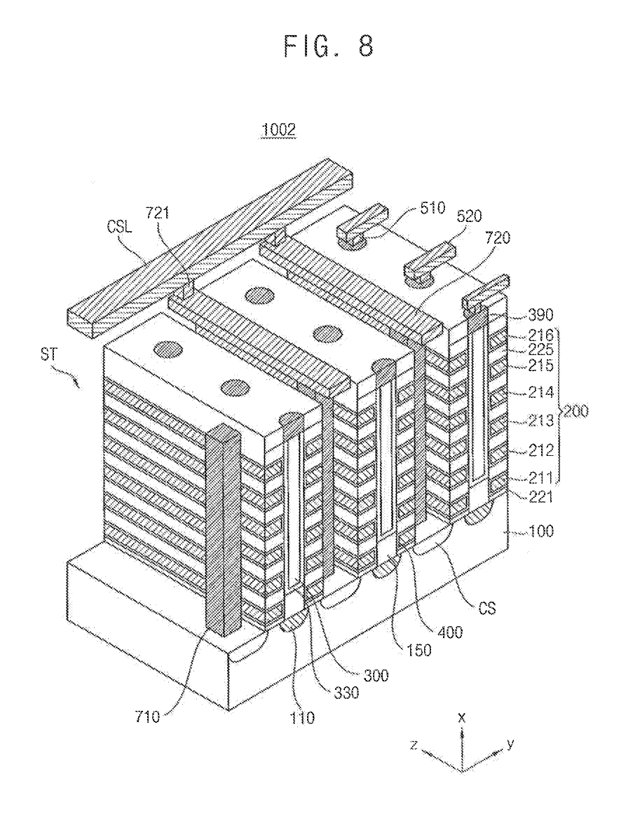

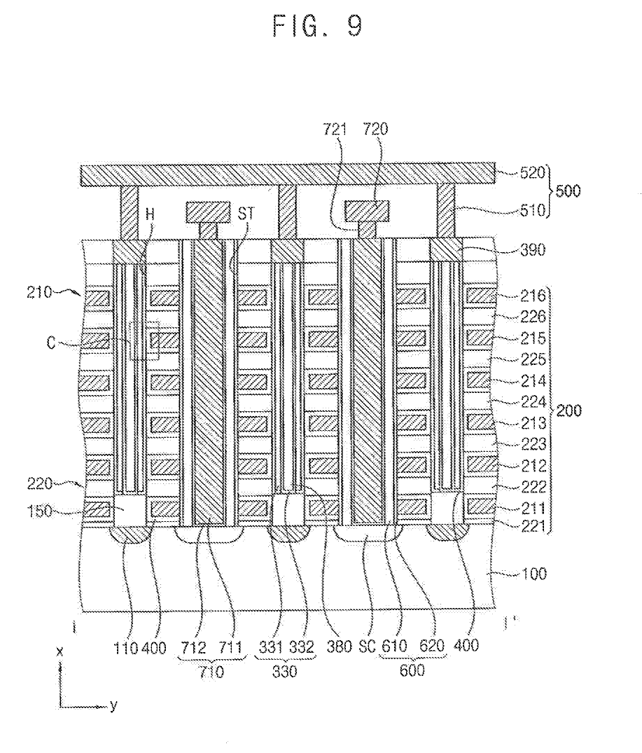

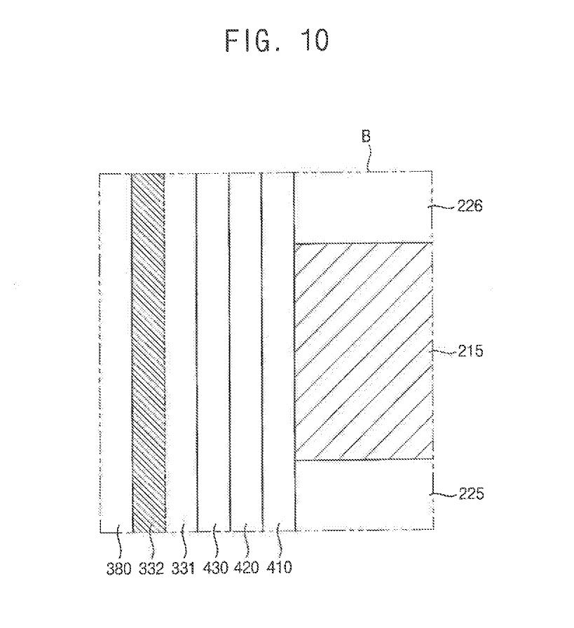

FIG. 8 is a perspective view illustrating a second modification of the vertical stack memory device shown in FIG. 1. FIG. 9 is a cross sectional view taken along a bit line of the vertical stack memory device shown in FIG. 8, and FIG. 10 is an enlarged view illustrating the charge storage structure of the second modified memory device shown in FIG. 8. For example, the memory cell C of the second modified memory device 1002 in FIG. 9 is illustrated in detail in FIG. 10.

In FIGS. 8 and 10, the second modified memory device 1002 may have substantially the same structures as the first modified memory device 1001 shown in FIGS. 6 and 7, except that the channel structure 300 comprises the low band gap materials. Thus, in FIGS. 8 to 10, the same reference numerals may denote the same element in FIGS. 6 and 7 and to the extent that further detailed descriptions on elements is omitted, it may be assumed that these elements are substantially the same as corresponding elements already disclosed.

Referring to FIGS. 8 to 10, a second modified memory device 1002 may include a low band gap channel 330 that may comprise low band gap materials and may make contact with the low resistive pattern 150.

For example, the low band gap channel 330 may include a semiconductor layer 331 and a low band gap film 332 disposed on the semiconductor layer 331. The semiconductor layer 331 may extend on the sidewall of the channel hole H in the first direction x in such a way that the charge storage structure 400 may be covered with the semiconductor layer 331 and the low resistive pattern may be partially exposed through the semiconductor layer 331. The low band gap materials may be deposited onto the semiconductor layer 331 in such a way that the semiconductor layer 331 and the low resistive pattern 150 may be sufficiently covered by the low band gap materials, thereby forming the low band gap film 332 on the semiconductor layer 331 and the low resistive pattern 150. The semiconductor layer 331 may comprise a silicon layer doped with departs and the low band gap film 332 may comprise the low band gap materials.

Thus, the semiconductor layer 331 may function as a semiconductor spacer for covering the charge storage structure 400 in the first direction x and the low band gap film 332 may he arranged on the semiconductor spacer and the low resistive pattern 150. The low band gap channel 330 may function as a channel layer for the second modified memory device 1002 in the channel hole H.

While it is disclosed that the second layer 312 of the semiconductor layer 310 of the first modified memory device 1001 shown in FIGS. 6 and 7 may be replaced with the low hand gap film 332, the second layer 312 of the semiconductor layer 310 of the vertical stack memory device 1000 shown in FIGS. 1 to 5 may also include the low band gap materials.

In such a case, the first layer 311 may include the doped silicon layer and the second layer 312 may include the low band gap materials just like the low band gap film 332. Thus, the first layer 311 may be covered with the low band gap materials from a top portion to a bottom portion of the channel hole H. Accordingly, the channel structure 300 of the vertical stack memory device 1000 may also be provided as a low band gap channel extending to the low band gap layer 110 in the channel hole H.

Therefore, the channel structure 300 of the vertical stack memory device 1000 and the first modified memory device 1001 may include low band gap materials. The low band gap materials for the channel structure 300 may be the same as or different from those of the low band gap layer 110. When the channel structure 300 includes the same low band gap materials as the low band gap layer 110, the low band gap layer 110 may extend substantially up to a top portion of the channel hole H. Thus, a plentiful supply of the electron holes may be generated from the low band gap layer 110 and the low band gap channel 330, thereby increasing the GIDL erase efficiency.

For example, when the channel hole H may be filled up with the low band gap materials without the insulative filler, the low band gap channel 330 may be shaped into a low band gap pillar in the channel hole H and the GIDL erase efficiency may substantially increase due to the abundance of the low band gap materials in the channel hole H.

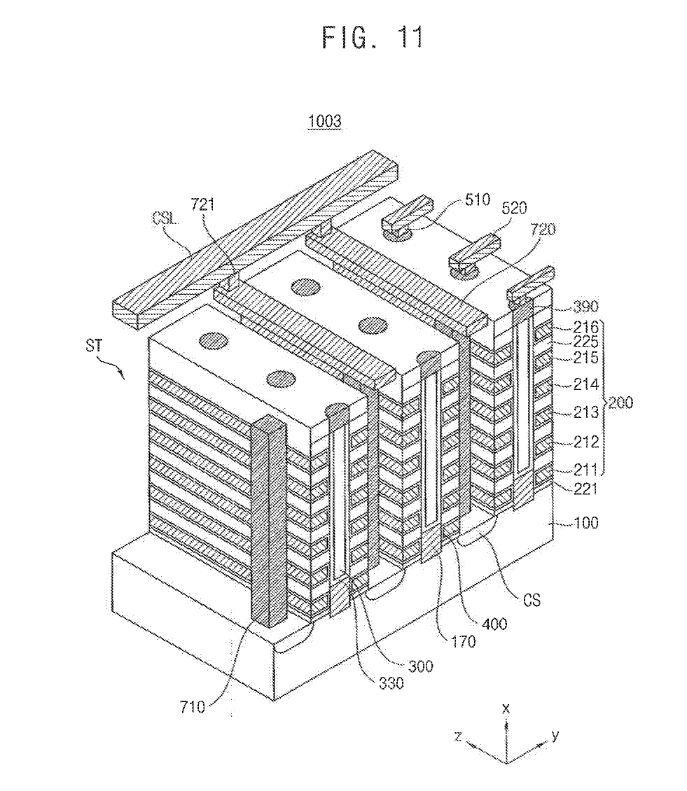

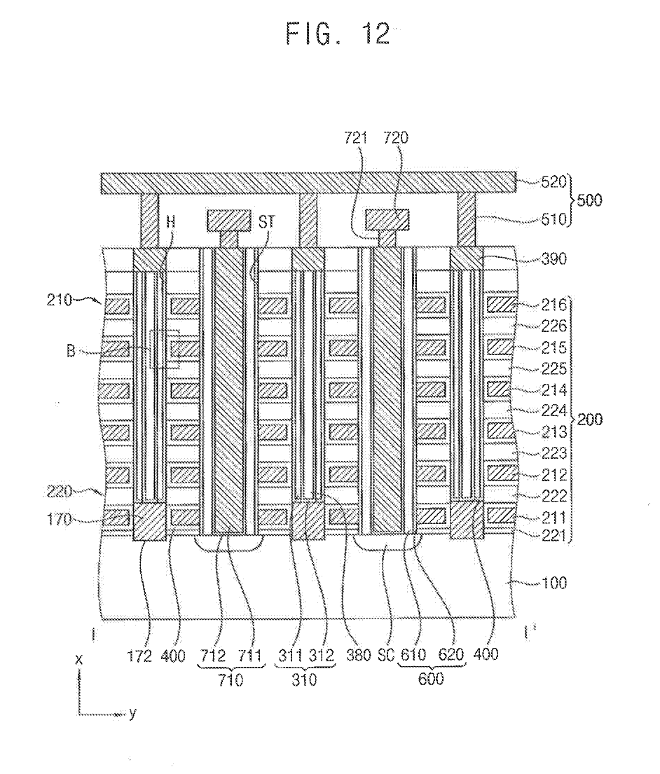

FIG. 11 is a perspective view illustrating a third modification of the vertical stack memory device shown in FIG. 1, and FIG. 12 is a cross sectional view taken along a bit line of the vertical stack memory device shown in FIG. 11.

In FIGS. 11 and 12, the third modified memory device 1003 may include a low band gap via-pattern 170 disposed between the substrate 100 and the channel structure 300, so the occupying area of the low band gap material may be minimized in the memory device to thereby increase the integration degree of the memory device,

Referring to FIGS. 11 and 12, a third modified memory device 1003 may include a semiconductor substrate 100 doped with dopants and having a common source CS to which a source power may be applied. A stack gate structure 200 may have gate electrodes and insulation interlayer patterns that are alternately and vertically stacked on the substrate 100 in a first direction x. A channel structure 300 penetrates through the stack gate structure 200 in the first direction x and connects to the substrate 100 through a low hand gap via-pattern 170 comprising low band gap materials. A charge storage structure 400 is interposed between the stack gate structure 200 and the channel structure 300. The charge storage structure 400 selectively stores charge to provide adequate charge to a memory cell C for storing data together with the stack gate structure 200 and the channel structure 300.

The low band gap materials may be arranged under the channel structure 300 on the substrate 100 as a via-pattern 170 for interconnecting the channel structure 300 with the substrate 100. The occupying area of the low band gap materials may have the same size as the cross-sectional surface of the channel hole H.

The substrate 100, the stack gate structure 200, the channel structure 300 and the charge storage structure 400 may have substantially the same structures as those of the vertical stack memory device 1000 shown in FIGS. 1 to 3, and thus it may be assumed that the detailed description of the substrate 100, the stack gate structure 200, the channel structure 300, and the charge storage structure 400 are substantially the same as those corresponding elements described above.

The substrate 100 may be partially exposed to the channel hole H penetrating through the stack gate structure 200 and a seed layer may be formed on a bottom of the channel hole H. The seed layer may comprise the low band gap materials.

Then, a selective epitaxial growth (SEG) process may be performed to the seed layer to a desired height in the channel hole H, thereby forming the low band gap via-pattern 170 at a lower portion of the channel hole H.

The low band gap materials may be diffused downwards into the substrate 100 in the SEG process and a lower portion of the low band gap via-pattern 170 may expand onto a surface portion of the substrate 100, to thereby form a diffusion portion 172 of the low band gap via-pattern 170. For example, the low band gap via-pattern 170 may be formed into an epitaxial pattern that may be grown upwards in the channel hole H from the surface portion of the substrate 100.

Thus, a surface profile of the low band gap via-pattern 170 may be substantially the same as that of the sidewall of the channel hole H and the occupying area of the low hand material may be substantially the same as the cross-sectional surface of the channel hole H.

The height of the low band gap via-pattern 170 from the substrate 100 may be changed by controlling the process conditions of the SEG process in a manner at least similar to that of the low resistive pattern 150.

The low band gap via-pattern 170 may also the same low band gap materials as the low band gap layer 110 of the vertical stack memory device 1000. Examples of the low band materials for the low band gap via-pattern 170 may include silicon germanium (SiGe), germanium (Ge), indium arsenide (InAs), gallium antimonids (GaSb), etc. These materials may be used alone or in combinations thereof.

Therefore, a larger amount of electron holes may be generated from the low band gap via-pattern 170 under the same drain power or without increase of the drain power, thereby increasing the GIDL erase efficiency in the third modified memory device 1003. For example, since the cross-sectional area of the low band gap via-pattern 170 may be the same as the cross-sectional surface of the channel hole H, the transfer path of the electron holes from the low band gap via-pattern 170 to the selection cell may be shortened. In addition, the hole density of the low band gap via-pattern 170 may be controlled merely by changing the height of the low band gap via-pattern 170 in the channel hole H.

Further, a depth of the diffusion portion 172 of the low band gap via-patter 170 may reduce the effective mess of the electron holes, so the transfer efficiency of the electron holes from the low band gap via-pattern 170 to the selection cell may be controlled merely by changing the depth of the diffusion portion 172.

When a silicon (Si) substrate may be provided as the substrate 100, the low band gap via-pattern 170 may have a lattice structure such that the inter-atomic distance of the low band gap via-pattern 170 may be greater than that of the silicon substrate. Thus, a compressive stress may be applied to the low band gap via-pattern 170 at a boundary area of the substrate 100 and the low band gap via-pattern 170, and the effective mass of the electron holes may be sufficiently reduced.

The boundary area of the low band gap via-pattern 170 may be varied by the depth of the diffusion portion 172 of the low band gap via-pattern 170, so the compressive stress may be changed by the diffusion portion 172.

Accordingly, the height of the low band gap via-pattern 170 in the channel hole H and the depth of the diffusion portion 172 may be changed by controlling the process conditions of the SEG process and the generation efficiency. The transfer efficiency of the electron holes may be varied by the height of the low band gap via-pattern 170 in the channel hole H and the depth of the diffusion portion 172. Thus, the process conditions of the SEG process for forming the low band gap via-pattern 170 may be controlled in such a way that the electron holes may be generated from the low band gap via-pattern, to the greatest extent possible, and the electron holes may be transferred to the selection cell from the low band gap via-pattern 170 as rapidly as possible, thereby increasing the GIDL erase efficiency in the third modified memory device 1003.

The channel structure 300 making contact with the low band gap via-pattern 170 may also comprise the low band gap materials as described in detail with reference to FIGS. 8 to 10, which may increase the GIDL erase efficiency.

In this case, the low band gap layer 110 may be disposed at the surface portions of the substrate 100, close to the drain region of the GST, and thus a sufficient amount of the electron holes may be generated from the low band gap layer 110 by minute GIDL currents. Therefore, the electron holes may be generated without any changes or increases of the drain power and a larger amount of the electron holes may be transferred to the selection cell, which may increase the GIDL erase efficiency.

In addition, the low band gap layer 110 may include a lattice structure such that the inter-atomic distance may be greater than that of surrounding structures (e.g., the substrate 100), so the compressive stress may be applied to the atoms of the low band gap layer 110 at the boundary area. Accordingly, the effective mass of the electron holes may be reduced due to the compressive stress and a larger amount of the electron holes may be transferred to the selection cell under the same control gate bias, thereby increasing the GIDL erase efficiency.

Exemplary embodiments described herein are illustrative, and many variations can be introduced without departing from the spirit of the disclosure or from the scope of the appended claims. For example, elements and/or features of different exemplary embodiments may be combined with each other and/or substituted for each other within the scope of this disclosure and appended claims.

What is claimed is:

1. A vertical stack memory device comprising:
a doped semiconductor substrate having a common source to which a source power is applied and a low band gap layer that is spaced apart from the common source, and the low band gap layer comprising low band gap materials;
a stack gate structure having gate electrodes and insulation interlayer patterns that are alternately and vertically stacked on the substrate in a first direction;
a channel structure penetrating through the stack gate structure in the first direction, the channel structure making contact with the low band gap layer; and
a charge storage structure interposed between the stack gate structure and the channel structure and selectively storing charge as a memory data, the gate electrode and the charge storage structure and the channel structure corresponding to the gate electrode being configured into a memory cell of the vertical stack memory device.

2. The vertical stack memory device of claim 1, wherein the low band gap material of the low band gap layer is activated by gate-induced drain leakage (GIDL) currents and the low band gap material is configured to generate electron holes, transfer the generated electron holes to the memory cell, and erase the charge in the memory cell.

3. The vertical stack memory device of claim 2, wherein the low band gap layer has a lattice structure of which an inter-atomic distance is greater than that of the substrate such that an effective mass of the electron hole is reduced by a compressive stress of the low band gap layer at a boundary area between the substrate and the band gap layer.

4. The vertical stack memory device of claim 1, wherein the substrate includes silicon (Si) and the low band gap layer includes at least one material selected from the group consisting of silicon germanium (SiGe), indium arsenide (InAs), gallium antimonids (GaSb), and compositions thereof.

5. The vertical stack memory device of claim 1, wherein the channel structure comprises a semiconductor material and includes one of a cylindrical layer and a column extending to the low band gap layer through the stack gate structure.

6. The vertical stack memory device of claim 5, further comprising a low resistive pattern interposed between the low band gap layer and the channel structure, the low resistive pattern configured to reduce contact resistance between the channel structure and the low band gap layer.

7. The vertical stack memory device of claim 6, wherein the low resistive pattern includes an epitaxial pattern that is formed by a selective epitaxial growth (SEG) process.

8. The vertical stack memory device of claim 6, wherein the low resistive pattern includes the low band gap materials.

9. The vertical stack memory device of claim 8, wherein the channel structure includes the low hand gap materials.

10. A vertical stack memory device comprising:
a doped semiconductor substrate having a common source configured to receive a source power;
a stack gate structure having gate electrodes and insulation interlayer patterns that are alternately and vertically stacked on the substrate in a first direction;
a channel structure penetrating through the stack gate structure in the first direction and connected to the substrate through a low band gap via-pattern comprising low band gap materials; and
a charge storage structure interposed between the stack gate structure and the channel structure and selectively storing charge as a memory data, the gate electrode and the charge storage structure and the channel structure corresponding to the gate electrode being configured into a memory cell of the vertical stack memory device.

11. The vertical stack memory device of claim 10, wherein the low band gap via-pattern extends into the substrate such that the low band gap via-pattern is spaced apart from the common source in the substrate and the low band gap material of the low band gap via-pattern is activated by gate-induced drain leakage (GIDL) currents and the low band gap material is configured to generate electron holes, transfer the generated electron holes to the memory cell, and erase the charge in the memory cell.

12. The vertical stack memory device of claim 11, wherein the low band gap via-pattern has a lattice structure of which an inter-atomic distance is greater than that of the substrate such that an effective mass of the electron hole is reduced by a compressive stress at a boundary area of the substrate and the low band gap via-pattern.

13. The vertical stack memory device of claim 10, wherein the semiconductor substrate includes silicon (Si) and the low band gap via-pattern includes at least one material selected from the group consisting of silicon germanium (SiGe), indium arsenide (InAs), gallium antimonide (GaSb), and compositions thereof.

14. The vertical stack memory device of claim 6, wherein the low band gap via-pattern includes an epitaxial pattern that is formed by a selective epitaxial growth (SEG) process.

15. The vertical stack memory device of claim 10, wherein the channel structure includes the low band gap materials.

16. A stacked memory device, comprising:
a semiconductor substrate;
a plurality of memory cells stacked vertically on the semiconductor substrate, wherein the semiconductor substrate includes a common source for the plurality of memory cells, and wherein the semiconductor substrate includes a low band gap layer comprising one or more low band gap materials;
a stack gate structure for the plurality of memory cells;
a channel structure for the plurality of memory cells; and
a charge storage structure configured to store charge and to provide the stored charge to the plurality of memory cells.

17. The stacked memory device of clam 16, wherein the low hand gap layer is spaced apart from the common source.

18. The stacked memory device of clam 16, wherein the stack gate structure includes a plurality of gate electrodes and a plurality of insulation interlayer patterns that are alternately and vertically stacked on the substrate.

19. The stacked memory device of dam 16, wherein the channel structure penetrates through the stack gate structure to make contact with the low band gap layer.

20. The stacked memory device of clam 16, wherein the charge storage structure is interposed between the stack gate structure and the channel structure.
